(19) United States
(12) Patent Application Publication
(10) Pub. No.: US 2007/0080463 A1
(43) Pub. Date: Apr. 12, 2007

(54) Semiconductor device and method of fabricating the same

(76) Inventor: Akira Furuya, Kanagawa (JP)

Correspondence Address: YOUNG & THOMPSON, 745 SOUTH 23RD STREET, 2ND FLOOR, ARLINGTON, VA, 22202, US

(21) Appl. No.: 11/540,599

(22) Filed: Oct. 2, 2006

(30) Foreign Application Priority Data
Oct. 3, 2005 (JP) 2005-289574

(51) Int. Cl. H01L 23/48

(52) U.S. Cl. 257/762

(57) ABSTRACT

A semiconductor device includes a semiconductor substrate, a lower insulating film formed on the semiconductor substrate, an interconnect-forming metal film provided so as to fill a recess formed in the surficial portion of the lower insulating film, and containing copper as a major constituent, an upper insulating film formed on the lower insulating film, and a metal-containing layer formed between the lower insulating film and the upper insulating film, and containing a metal different from copper. The metal-containing layer includes a first region in contact with the interconnect-forming metal film, and a second region in contact with the lower insulating film, and having a composition different from that of the first region, and contains substantially no nitrogen at least in the first region.

This application is based on Japanese patent application No. 2005-289574 the content of which is incorporated hereinto by reference.

### BACKGROUND

1. Technical Field

The present invention relates to a semiconductor device and a method of fabricating the same.

2. Related Art

In recent years, signal delay on interconnects has limit the operation speed of semiconductor devices. A delay constant of signal on an interconnect is expressed by a product of interconnect resistance and interconnect capacitance. For this reason, there has been an increasing trend of using a material having a dielectric constant smaller than that of conventional SiO₂ for composing an interlayer insulating film, in order to lower the interconnect resistance and to thereby increase operation speed of the device. There has been also an increasing trend of using copper, having a small specific resistivity, as a material for composing the interconnect.

Multi-layered copper interconnect is formed by the damascene process described below. First, an interlayer insulating film is formed on a semiconductor substrate. Interconnect trenches or via-holes are then formed in the interlayer insulating film. Next, a barrier metal film is formed in the interconnect trenches or the via-holes, and a copper film is filled in the interconnect trenches or the via-holes. Excessive portions of the barrier metal and the copper film exposed outside of the interconnect trenches or the via-holes are then removed by chemical mechanical polishing (CMP). The copper multi-layered interconnect can be formed by repeating these processes.

A technique having been arisen in recent years relates to improvement in migration resistance, by selectively forming a cap metal on the upper surface of the copper interconnect. In this context, investigations have been made on selective growth of the cap metal layer on the surface of the copper interconnect, in view of ensuring a desirable level of isolation property between the adjacent copper interconnects. This sort of selective growth is exemplified by formation of CoWP by electroless plating. However, such selective growth has occasionally resulted in only an insufficient selectivity in the formation of cap metal, and has caused deposition of the cap metal also on the top surface of the interlayer insulating film, not only on the top surface of the copper interconnect, raising a fear of inducing interconnect leakage.

Japanese Laid-Open Patent Publication No. H11-186273 discloses a semiconductor device having an anti-oxidative barrier, aimed at preventing oxidation of the interconnects, formed on a copper interconnect containing a predetermined element. The anti-oxidative barrier herein is composed of an oxide of the predetermined element contained in the copper interconnect. The method, however, forms the protective film by allowing Mg, for example, solubilized in the solid of the interconnect layer to diffuse into the surficial portion of the interconnect layer, so that the process was less controllable.

As has been described in the above, it has been difficult to selectively form the barrier film or the like, only on the surface of the copper interconnect.

As one conventional technique of solving this problem, there is known a technique of forming, by ALD (atomic layer deposition), a TaNx film showing different characteristics on the copper interconnect and on a low-k film (Hsien-Ming Lee, “High Performance Cu Interconnects Capped with Full-Coverage ALD TaNx layer for Cu/Low-k Metallization”, International Interconnect Technology Conference, Jun. 7-9, 2004). The technique described in this publication relates to formation of a TaNx film on both of the copper interconnect and the low-k film. This technique is, so as to say, forming the cap metal over the entire surface of the copper interconnect and the interlayer insulating film, not only on the top surface of the copper interconnect.

### SUMMARY OF THE INVENTION

The conventional techniques described in the foregoing literatures have been remained for future improvement in the aspect below.

That is, the present inventors found out a problem in that adhesiveness between the copper film and the cap metal film degrades, when the TaNx film as described in the aforementioned non-patent literature was used as the cap metal film.

According to the present invention, there is provided a semiconductor device which includes:

a semiconductor substrate;

a first insulating film formed on the semiconductor substrate;

a copper-containing metal film provided so as to fill a recess formed in the surficial portion of the first insulating film, and containing copper as a major constituent;

a second insulating film formed on the first insulating film; and

a metal-containing layer formed between the first insulating film and the second insulating film, and containing a metal element different from copper,

wherein the metal-containing layer includes a first region in contact with the copper-containing metal film, and a second region in contact with the first insulating film and having a composition different from that of the first region, and contains substantially no nitrogen at least in the first region.

According to the present invention, there is also provided a method of fabricating a semiconductor device which includes:

forming a first insulating film on a semiconductor substrate;

forming a recess in the surficial portion of the first insulating film;

filling the recess with a copper-containing metal film containing copper as a major constituent;

removing the excessive portion of the copper-containing metal film exposed outside the recess;

forming, over the entire surface of the first insulating film, a metal layer containing a metal element different from copper and containing substantially no nitrogen;

forming a second insulating film on the metal layer; and

forming, in the metal layer by annealing, a first region in contact with the copper-containing metal film, and a second region in contact with the first insulating film and having composition different from that of the first region.

In the present invention, the metal-containing layer may be formed by forming, over the entire surface of the first insulating film, the metal layer containing a metal element and containing substantially no nitrogen, and then by allowing, by annealing, the element contained in the material in contact with the metal layer into the metal layer. In other words, in regions where the metal layer comes into contact respectively with the first insulating film, the second insulating film and the copper-containing metal film, the elements contained in these films are allowed to diffuse into the metal layer. As a consequence, the metal-containing layer is typically allowed to contain, in the second region, the element contained in the first insulating film and the second insulating film, and to show an insulating property. The metal-containing layer is also allowed to contain, in the first region, the element contained in the copper-containing metal film and the second insulating film, and thereby to function as a cap film for the copper-containing metal film.

The metal-containing layer contains substantially no nitrogen in the first region formed on the copper-containing metal film, so that adhesiveness between the metal-containing layer and the copper-containing metal film can be improved. Reliability of the semiconductor device can thus be improved. It is to be noted that the metal-containing layer may contain a trace amount of nitrogen unintentionally introduced in the process of fabrication.

The present invention can successfully improve reliability of the copper interconnect.

### BRIEF DESCRIPTION OF THE DRAWINGS

The above and other objects, advantages and features of the present invention will be more apparent from the following description taken in conjunction with the accompanying drawings, in which:

FIGS. 1A and 1B are sectional views showing exemplary configurations of a semiconductor device according to an embodiment of the present invention;

FIG. 2 is a flow chart showing procedures of fabricating the semiconductor device according to the embodiment of the present invention;

FIGS. 3A to 3D are sectional views showing an exemplary procedure for fabricating a semiconductor device according to a first embodiment of the present invention;

FIGS. 4A to 4D are sectional views showing another exemplary procedure for fabricating a semiconductor device according to the first embodiment of the present invention;

FIGS. 5A to 5D are sectional views showing an exemplary procedure for fabricating a semiconductor device according to a second embodiment of the present invention;

FIGS. 6A to 6D are sectional views showing another exemplary procedure for fabricating a semiconductor device according to the second embodiment of the present invention;

FIGS. 7A to 7D are sectional views showing an exemplary procedure for fabricating a semiconductor device according to a third embodiment of the present invention;

FIGS. 8A to 8D are sectional views showing another exemplary procedure for fabricating a semiconductor device according to the third embodiment of the present invention;

FIGS. 9A to 9D are sectional views showing an exemplary procedure for fabricating a semiconductor device according to a fourth embodiment of the present invention; and

FIGS. 10A to 10D are sectional views showing another exemplary procedure for fabricating a semiconductor device according to the fourth embodiment of the present invention.

### DETAILED DESCRIPTION

The invention will be now described herein with reference to an illustrative embodiment. Those skilled in the art will recognize that many alternative embodiments can be accomplished using the teachings of the present invention and that the invention is not limited to the embodiment illustrated for explanatory purposes.

Paragraphs below will describe embodiments of the present invention. Any similar constituents appear in all of the attached drawings will be given with the same reference numerals, and the explanations therefor will not be repeated.

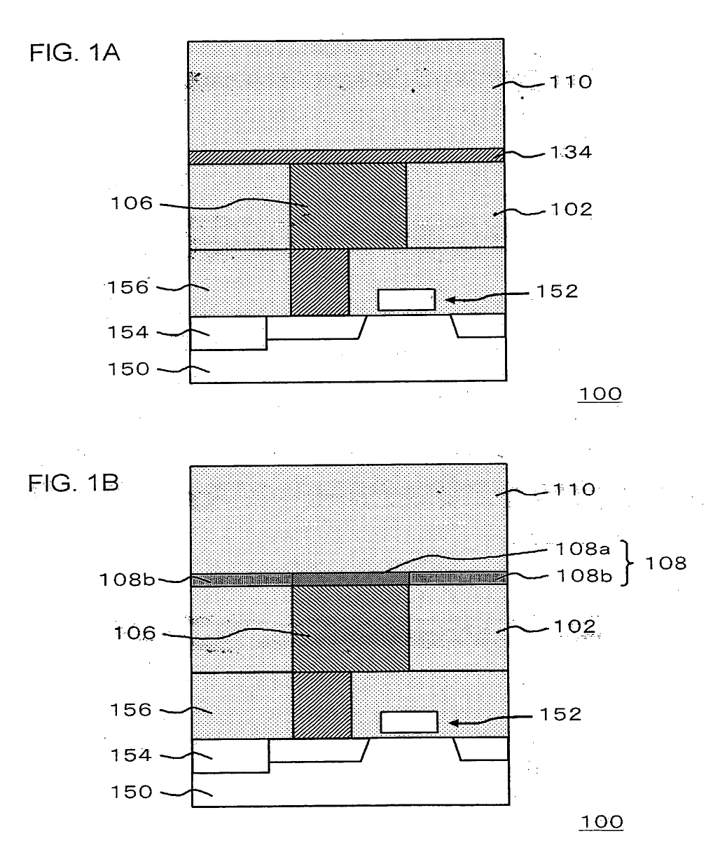

FIGS. 1A and 1B are sectional views schematically showing a configuration of a semiconductor device according to one embodiment of the present invention.

First, as shown in FIG. 1A, obtained herein is a semiconductor device, in which, on a semiconductor substrate 150 having a device such as a transistor 152 and a device isolation region 154 formed thereon and on an interlayer insulating film 156, a lower insulating film 102 (first insulating film), an interconnect-forming metal film 106 (copper-containing metal film) provided so as to fill a recess formed in the lower insulating film 102 and containing copper as a major constituent, an upper insulating film 110 (second insulating film) formed on the lower insulating film 102, and a metal layer 134 formed between the lower insulating film 102 and the upper insulating film 110 and containing a metal element M different from copper and containing substantially no nitrogen are formed. Although not shown in the drawing, a barrier metal layer may be formed in the recess to cover the bottom surface and the side surface thereof. The interconnect-forming metal film 106 may be formed on the barrier metal layer to fill the recess. The entire portion of thus-configured base structure is annealed to thereby obtain the semiconductor device 100 configured as shown in FIG. 1B. Although the interconnect-forming metal film 106 herein is exemplified as the lowermost interconnect, the interconnect-forming metal film 106 may be provided in any other layers.

As shown in FIG. 1B, by the annealing, the metal layer 134 is converted to a metal-containing layer 108a which includes a first region 108a in contact with the interconnect-forming metal film 106, and a second region 108b in contact with the lower insulating film 102 and having a composition different from that of the first region 108a. The metal-containing layer 108 is configured as containing substantially no nitrogen at least in the first region 108a. In this embodiment, the second region 108b is configured by a material showing an insulating property, and the first region 108a is configured as functioning as a cap film for the interconnect-forming metal film 106.

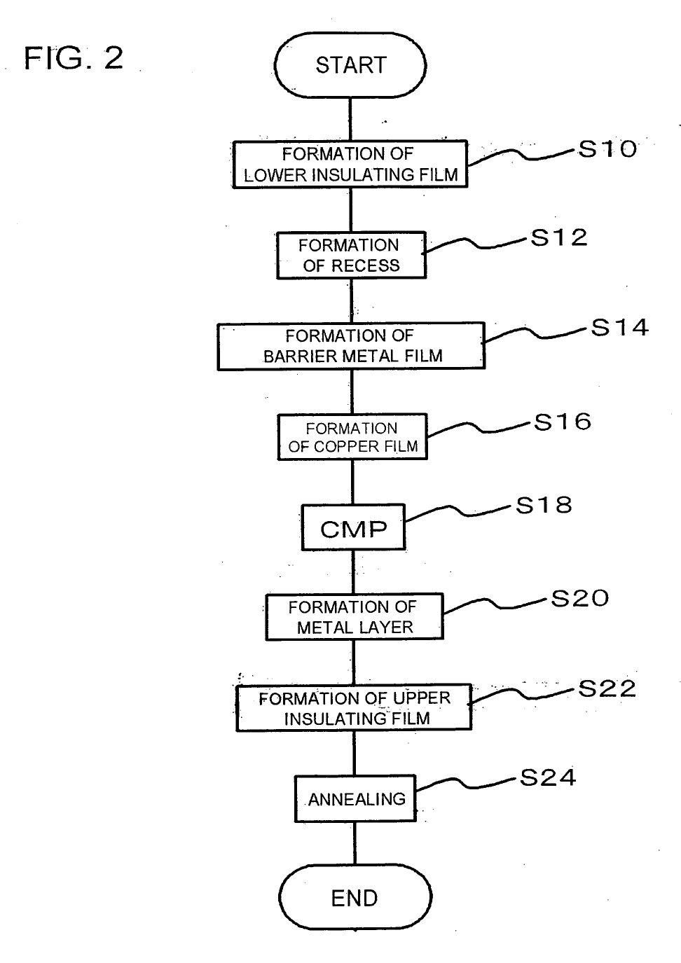

FIG. 2 is a flow chart showing procedures of fabricating the semiconductor device 100 according to the embodiment of the present invention. The procedures will be explained below, referring also to FIGS. 1A and 1B.

In this embodiment, first the lower insulating film 102 is formed on the semiconductor substrate 150 and the interlayer insulating film 156 (S10). Next, the recess is formed in the lower insulating film 102 (S12). Next, the barrier metal film is formed in the recess (S14). Thereafter, the copper film is formed in the recess so as to fill it up (S16). The excessive portions of the copper film and the barrier metal film formed outside the recess are removed by CMP (S18). The interconnect-forming metal film 106 is thus formed by these processes.

Next, the metal layer 134 containing the metal element M different from copper, but containing substantially no nitrogen is formed over the entire portion of the base structure (S20). Thereafter, the upper insulating film 110 is formed on the metal layer 134 (S22). Next, the entire portion of the base structure is annealed (S24).

In the annealing in step S24 of this embodiment, the elements respectively contained in the lower insulating film 102, the upper insulating film 110, and in the interconnect-forming metal film 106 are allowed to diffuse into the metal layer 134 in contact therewith, to thereby form the metal-containing layer 108 having therein the first region 108a and the second region 108b.

In this embodiment, the lower insulating film 102 and the upper insulating film 110 can be configured by a material containing an element, introduction of which into the metal layer 134 can convert the metal layer 134 so as to show an insulating property in the second region 108b, and so as to function as a cap film for the interconnect-forming metal film 106 in the first region 108a. The metal element M contained in the metal layer 134 may be a metal capable of incorporating the above-described element contained in the lower insulating film 102 and the upper insulating film 110.

The lower insulating film 102 can be configured typically by a material containing silicon and oxygen. The metal element M may be a metal which can be oxidized by oxygen contained in the lower insulating film 102. This configuration makes the metal element M of the metal layer 134 in the second region 108b in contact with the lower insulating film 102 more ready to be oxidized in the annealing in step S24. By this process, the metal-containing layer 108 can be made as showing an insulating property in the second region 108b thereof.

In this embodiment, also the upper insulating film 110 may be configured by a material containing silicon and oxygen. In this configuration, the metal element M of the metal layer 134 in the first region 108a and the second region 108b in contact with the upper insulating film 110 is oxidized by oxygen in the upper insulating film 110, during the annealing in step S24. By this process, the metal-containing layer 108 can be made as showing an insulating property in the second region 108b. In addition, by this process, the metal-containing layer 108 can function as a cap film for the interconnect-forming metal film 106 in the first region 108a thereof.

As this sort of metal element M, a metal selected from the group consisting of Mn, Ta, Al and Ti may typically be used.

In this embodiment, each of the lower insulating film 102 and the upper insulating film 110 may be a low-k film typically having a dielectric constant of 3.3 or below, and more preferably 2.9 or below. The lower insulating film 102 and the upper insulating film 110 may be configured by a material containing no nitrogen. The lower insulating film 102 and the upper insulating film 110 may be configured typically by SiOC (SiOCH), methyl silsesquioxane (MSQ), hydrogenated methyl silsesquioxane (MHSQ), organic polysiloxane, and any films of these materials modified to the porous ones. The lower insulating film 102 and the upper insulating film 110 may be configured by the same material, or by different materials.

The metal element M may be a silicide-forming metal capable of forming a silicide. As described in the above, for the case where the lower insulating film 102 and the upper insulating film 110 are composed of a silicon-containing material, the metal element M in the metal-containing layer 108 is converted to a silicide, in the regions in contact with the lower insulating film 102 and/or the upper insulating film 110. This process can modify the metal layer 134, and can therefore further enhance the insulating property in the second region 108b, and can further enhance the function of the first region 108a as a cap film.

As this sort of metal element M, a metal selected from the group typically consisting of Mn, Al and Ti can be used. Also the metal element M can typically be a metal capable of producing a compound with oxygen and/or silicon with an energy of formation almost equivalent to, or smaller than that of free energy of formation of silicon oxide.

For the case where the metal element M is a material capable of forming an alloy with copper composing the interconnect-forming metal film 106, such alloy of copper and the metal element M is formed in the first region 108a. Therefore, it is also made possible to improve the electro-migration resistance of the interconnect-forming metal film 106. As this sort of metal element M, a metal selected from the group typically consisting of Mn, Al and Ti can be used.

The explanation in the above showed the case where the annealing was carried out in step S24, whereas the annealing may appropriately be carried out during, or after the formation of the metal layer 134 in step S22, or during or after the formation of the upper insulating film 110 in step S22. These processes can make the metal-containing layer 108 show an insulating property in the second region 108b, and can make the metal-containing layer 108 function as a cap film for the interconnect-forming metal film 106 in the first region 108a.

By the processes described in the above, the metal-containing layer 108 is formed as having the first region 108a in contact with the interconnect-forming metal film 106, and a second region 108b in contact with the lower insulating film 102 and having a composition different from that of the first region 108a.

The metal-containing layer 108 herein is composed of a material containing substantially no nitrogen. This embodiment is therefore successful in ensuring a desirable level of adhesiveness between the metal-containing layer 108 and the underlying interconnect-forming metal film 106.

### First Embodiment

In this embodiment, the metal-containing layer 108 contains a metal element M₁. In this embodiment, the metal element M₁ may be a metal capable of forming an oxide. In this embodiment, the metal element M₁ may also be a silicide-forming metal capable of forming a silicide. In this embodiment, the metal element M₁ may still also be a metal capable of forming an alloy with copper. In this embodiment, the metal element M₁ may be selected from the group consisting of Mn, Al and Ti.

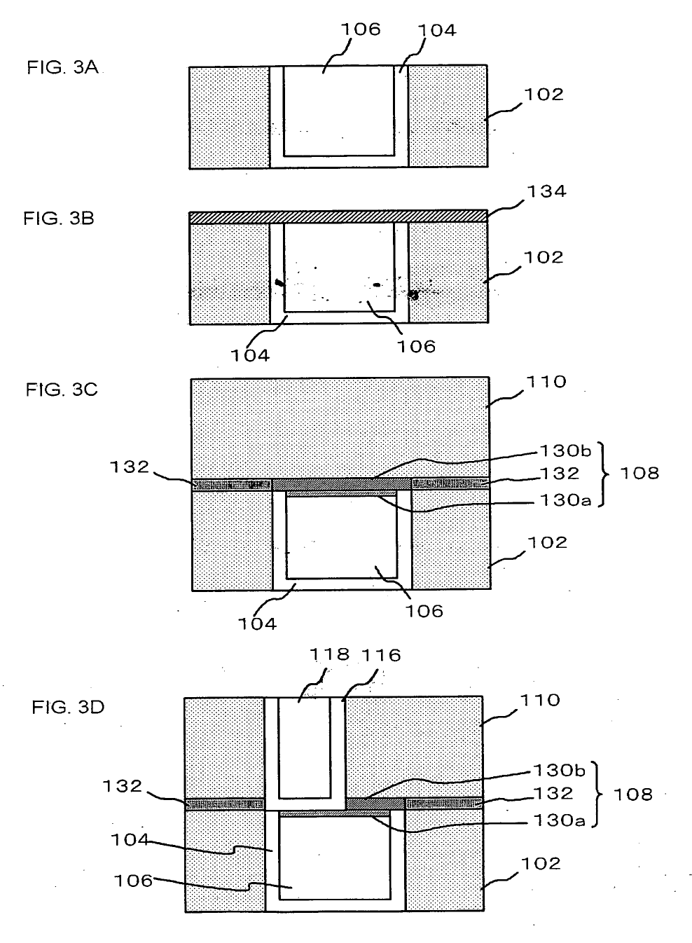

FIGS. 3A to 3D are sectional views showing an exemplary procedure for of fabricating the semiconductor device 100 of this embodiment.

First, similarly to as shown in FIG. 1A, the lower insulating film 102 is formed on the semiconductor substrate (not shown) having devices such as transistors formed thereon. Next, the interconnect trench is formed in the lower insulating film 102, and the interconnect trench is filled with the barrier metal film 104 and the interconnect-forming metal film 106. The barrier metal film 104 may typically be Ta/TaN, Ti, TiN, TiSiN, Ta, TaN, TaSiN or the like. The interconnect-forming metal film 106 may be configured by a copper-containing metal film containing copper as a major constituent. Thereafter, excessive portions of the interconnect-forming metal film 106 and the barrier metal film 104 exposed outside the interconnect trench are removed by CMP. The interconnect structure shown in FIG. 3A is thus obtained.

Next, the metal layer 134 containing the metal element M₁ but containing substantially no nitrogen is formed on the lower insulating film 102 by the PVD (physical vapor deposition) process. The thickness of the metal layer 134 is typically set to 1 to 5 nm or around.

Next, the upper insulating film 110 is formed on the metal layer 134 (FIG. 3C). In this embodiment, the lower insulating film 102 and the upper insulating film 110 may be configured by a low-k film as previously explained referring to FIGS. 1A and 1B. The upper insulating film 110 may be formed typically by the CVD (chemical vapor deposition) process at around 100 to 400° C.

Because the entire portion of the base structure is exposed to heat during formation of the upper insulating film 110, the metal layer 134 disposed between the lower insulating film 102 and the upper insulating film 110 is introduced with silicon (Si) and oxygen (O) contained in these insulating films. An M₁-Si—O-containing layer 132 is thus formed. The region of the metal layer 134 formed on the interconnect-forming metal film 106 allows a part thereof to diffuse into the copper interconnect, to thereby form a Cu-M₁-containing layer 130a. The region of the metal layer 134 formed on the interconnect-forming metal film 106 and in contact with the upper insulating film 110 is introduced with silicon and oxygen in the upper insulating film 110, and is converted to an M₁-Si—O-containing layer 130b. For the case where the metal element M₁ is a silicide-forming metal capable of forming a silicide, such silicide of the metal element M₁ is formed in the M₁-Si—O-containing layer 132 and the M₁-Si—O-containing layer 130b. For the case where the metal element M₁ is a metal capable of forming an alloy with copper, such alloy of copper and the metal element M₁ is formed in the Cu-M₁-containing layer 130a.

Next, the via-hole is formed in the upper insulating film 110. In this process, also the M₁-Si—O-containing layer 130b at the bottom of the via-hole is removed, to thereby allow the Cu-M₁-containing layer 130a to expose at the bottom of the via-hole. Next, the via-hole is filled up with a barrier metal film 116 and a via-plug 118. The via-plug 118 may be configured by a copper-containing metal film containing copper as a major constituent. The via-plug 118 may be formed by plating. After the plating, the product is annealed at around 150 to 400° C. in an N₂ atmosphere. By this process, the entire portion of the base structure is further exposed to heat, and the M₁-Si—O-containing layer 132 comes to show an insulating property due to its increased contents of oxygen and silicon. The oxygen and silicon contents increase also in the M₁-Si—O-containing layer 130b, so that also the M₁-Si—O-containing layer 130b can exhibit an insulating property. Because the Cu-M₁-containing layer 130a is electro-conductive, the interconnect-forming metal film 106 and the via-plug 118 herein are electrically connected. Thereafter, the excessive portions of the via-plug 118 and the barrier metal film 116 exposed outside the via-hole are removed by CMP. The semiconductor device 100 configured as shown in FIG. 3D is thus obtained.

As has been described in the above, the semiconductor device 100 of this embodiment can be formed so that the metal layer 134 formed over the entire surface of the base structure can exhibit an insulating property selectively in the region in contact with the insulating film. In addition, because the metal-containing layer 108 contains substantially no nitrogen, a desirable level of adhesiveness between the interconnect-forming metal film 106 and the metal-containing layer 108 can be ensured. Formation of the Cu-M₁-containing layer 130a on the interconnect-forming metal film 106 can improve the electro-migration resistance of the interconnect-forming metal film 106. For the case where the metal-containing layer 108 contains silicon and so that the metal element M₁ is silicided, the insulating property of the M₁-Si—O-containing layer 132 and the M₁-Si—O-containing layer 130b can be improved. Further, for the case where the metal element M₁ is capable of forming an alloy with copper, the electro-migration resistance of the interconnect-forming metal film 106 can further be improved by virtue of the Cu-M₁-containing layer 130a.

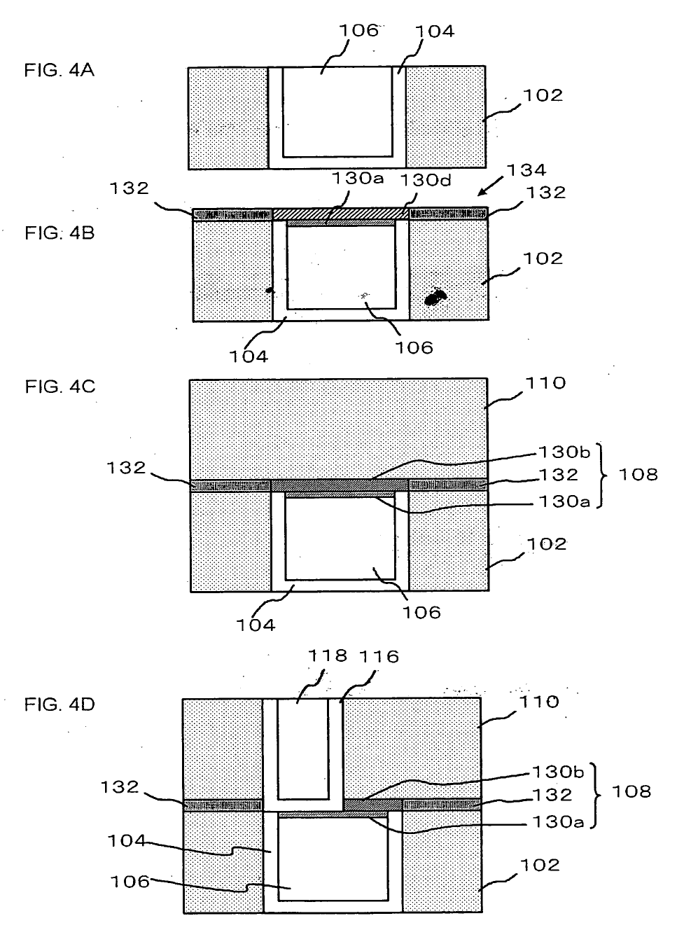

FIGS. 4A to 4D are drawings showing another exemplary procedure for fabricating the semiconductor device 100 of this embodiment.

This example differs from the example shown in FIGS. 3A to 3D, in that the metal layer 134 is formed by the ALD process or the CVD process.

The interconnect structure shown in FIG. 4A is formed according to a procedure similar to that explained referring to FIG. 3A. Next, the metal layer 134 is formed on the lower insulating film 102, by the ALD process or the CVD process, at approximately 100 to 250° C. (FIG. 4B). The metal layer 134 contains the metal element M₁ similar to that explained referring to FIG. 3B, but contains substantially no nitrogen. Because heat is applied during the formation of the metal layer 134, the M₁-Si—O-containing layer 132 is formed in the metal layer 134 specifically in the region in contact with the lower insulating film 102. Also the Cu-M₁-containing layer 130a is formed in the metal layer 134 specifically in the region in contact with the interconnect-forming metal film 106. On the Cu-M₁-containing layer 130a and on the barrier metal film 104, an M₁-containing layer 130d is formed.

Next, the upper insulating film 110 is formed on the metal layer 134 (FIG. 4C). The upper insulating film 110 can be formed typically by the CVD process at around 100 to 400° C. The entire portion of the base structure is exposed to heat in this process, and oxygen and silicon also in the upper insulating film 110 diffuse into the M₁-Si—O-containing layer 132 and the M₁-containing layer 130d. As a consequence, the oxygen and silicon contents of the M₁-Si—O-containing layer 132 increase. The M₁-containing layer 130d is converted to the M₁-Si—O-containing layer 130b.

Thereafter, similarly to as explained in the above referring to FIG. 3D, the via-plug 118 and the barrier metal film 116 are formed in the upper insulating film 110 (FIG. 4D). Because the entire portion of the base structure is exposed to heat in the process of forming the via-plug 118, the M₁-Si—O-containing layer 132 and the M₁-Si—O-containing layer 130b, in contact with the lower insulating film 102 or with the upper insulating film 110, are further increased in the oxygen and silicon contents, and thereby become to show insulating properties.

The description in the above showed the exemplary case where the metal layer 134 was converted to the metal-containing layer 108 by annealing in the process of forming the upper insulating film 110 and the via-plug 118. It is, however, also allowable to form the metal-containing layer 108 by independent annealing typically after the formation of the metal layer 134 on the lower insulating film 102, or after the formation of the upper insulating film 110.

For example, the metal element M₁ may be Mn. In this case, as shown in FIG. 3A, the interconnect-forming metal film 106 typically composed of a copper-containing metal film is formed in the lower insulating film 102 composed of a low-k film such as a SiOC film. The excessive portion of the interconnect-forming metal film 106 is removed by CMP for planarization, and a Mn film (approximately 1 to 5 nm) is formed by the PVD process on the lower insulating film 102. The entire portion of the base structure is then annealed at 100 to 400° C. By this process, a MnSixOy film is formed in the second region 108b on the lower insulating film 102, based on diffusion of the element from the lower insulating film 102. On the other hand, a CuMn alloy is formed in the first region 108a on the interconnect-forming metal film 106.

As has been described in the above, in this embodiment, the M₁-Si—O-containing layer 132 having an insulating property is formed on the lower insulating film 102, and the Cu-M₁-containing layer 130a and the M₁-Si—O-containing layer 130b are formed on the interconnect-forming metal film 106. Because the metal-containing layer 108 contains no nitrogen, a desirable level of adhesiveness is ensured between the metal-containing layer 108 and the interconnect-forming metal film 106. As a consequence, the reliability of the semiconductor device 100 can be improved.

### Second Embodiment

This embodiment differs from the first embodiment in species of the metal contained in the metal-containing layer 108. In this embodiment, the metal-containing layer 108 contains a metal element M₂. In this embodiment, the metal element M₂ may be a non-silicide-forming metal. In this embodiment, the metal element M₂ may typically be Ta.

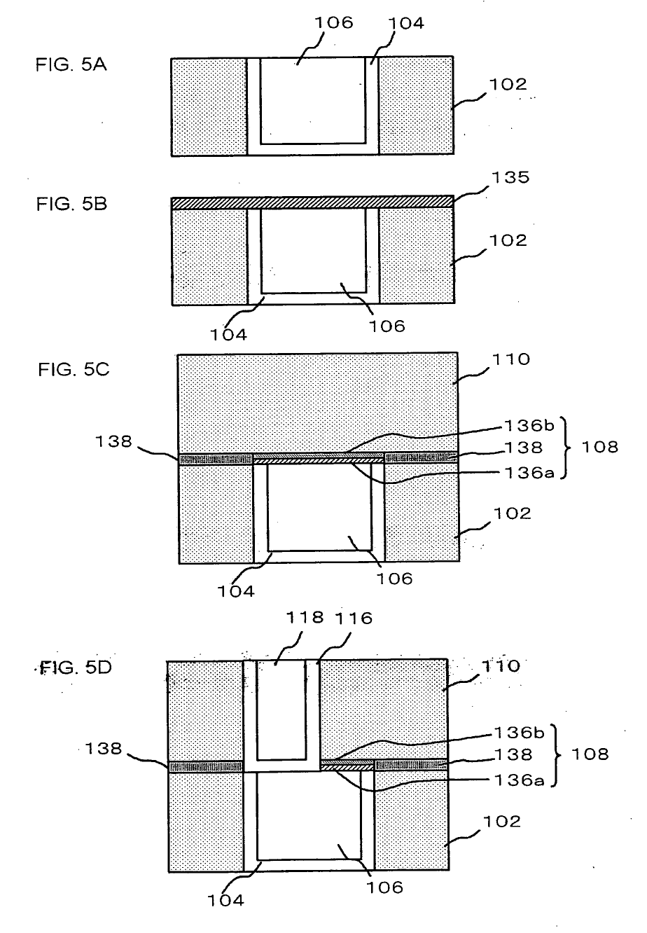

FIGS. 5A to 5D are drawings showing an exemplary procedure for fabricating the semiconductor device 100 of this embodiment.

The interconnect structure shown in FIG. 5A is formed, according to the procedure explained in the first embodiment referring to FIG. 3A. Next, a metal layer 135 containing the metal element M₂ but containing substantially no nitrogen is formed on the lower insulating film 102 by the PVD process (FIG. 5B). The thickness of the metal layer 135 is typically adjusted to approximately 1 to 5 nm.

Next, the upper insulating film 110 is formed on the metal layer 135 (FIG. 5C). The upper insulating film 110 can be formed typically by the CVD process at 100 to 400° C. or around. In this process, the entire portion of the base structure is exposed to heat, and the region of the metal layer 135 disposed between the lower insulating film 102 and the upper insulating film 110 is converted to an M₂-O-containing layer 138. The metal layer 135 on the interconnect-forming metal film 106 is converted to an M₂-O-containing layer 136b specifically in the region in contact with the upper insulating film 110, as being formed on an M₂-containing layer 136a remained intact.

Thereafter, similarly to as explained in the first embodiment referring to FIG. 3D, the via-plug 118 and the barrier metal film 116 are formed in the upper insulating film 110 (FIG. 5D). Because the entire portion of the base structure is exposed to heat in the process of forming the via-plug 118, the M₂-O-containing layer 138 and the M₂-O-containing layer 136b, in contact with the lower insulating film 102 or with the upper insulating film 110, are further increased in the oxygen content, and thereby become to show insulating properties. The M₂-O-containing layer 138 herein is brought into contact with the lower insulating film 102 and the upper insulating film 110, respectively on the upper side thereof and the lower side thereof, so that oxygen content thereof becomes larger than that of the M₂-O-containing layer 136b.

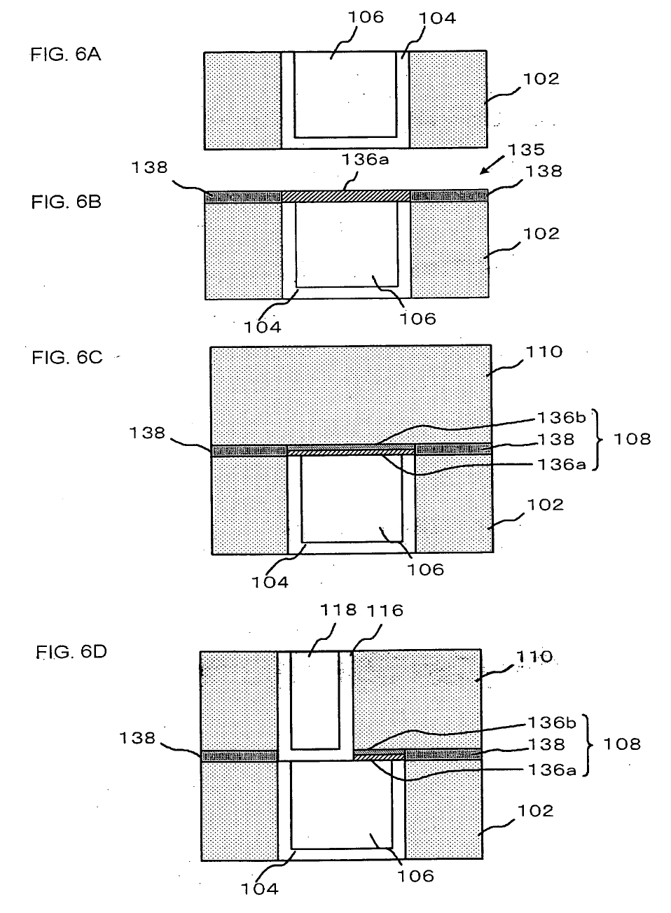

FIGS. 6A to 6D are drawings showing another exemplary procedure for fabricating the semiconductor device 100 of this embodiment.

This embodiment differs from the example shown in FIGS. 5A to 5D in that the metal layer 135 is formed by the ALD process or the CVD process.

The interconnect structure shown in FIG. 6A is formed according to the procedure similar to that explained in the first embodiment referring to FIG. 3A. Next, the metal layer 135 is formed on the lower insulating film 102 by the ALD process or the CVD process at approximately 100 to 250° C. (FIG. 6B). The metal layer 135 contains the metal element M₂ similar to that explained referring to FIG. 5B, but contains substantially no nitrogen. Because of heat applied in the process of forming the metal layer 135, the M₂-O-containing layer 138 is formed in the metal layer 135 specifically in the region in contact with the lower insulating film 102, and the M₂-containing layer 136a is formed in the region in contact with the interconnect-forming metal film 106.

Next, the upper insulating film 110 is formed on the metal layer 135 (FIG. 6C). The upper insulating film 110 can be formed typically by the CVD process at approximately 100 to 400° C. The entire portion of the base structure is exposed to heat in this process, and oxygen also in the upper insulating film 110 diffuses into the M₂-O-containing layer 138 and the M₂-containing layer 136a. As a consequence, the oxygen content of the M₂-O-containing layer 138 increases. A part of the M₂-containing layer 136a in contact with the upper insulating film 110 is converted to the M₂-O-containing layer 136b.

Thereafter, similarly to as explained in the first embodiment referring to FIG. 3D, the via-plug 118 and the barrier metal film 116 are formed in the upper insulating film 110 (FIG. 6D). Because the entire portion of the base structure is exposed to heat in the process of forming the via-plug 118, the M₂-O-containing layer 138 and the M₂-O-containing layer 136b, in contact with the lower insulating film 102 or with the upper insulating film 110, are further increased in the oxygen content, and thereby become to show insulating properties.

As has been described in the above, in this embodiment, the M₂-O-containing layer 138 having an insulating property is formed on the lower insulating film 102, and the M₂-containing layer 136a and the M₂-O-containing layer 136b are formed on the interconnect-forming metal film 106. Because the metal-containing layer 108 contains no nitrogen, a desirable level of adhesiveness is ensured between the metal-containing layer 108 and the interconnect-forming metal film 106. As a consequence, the reliability of the semiconductor device 100 can be improved.

### Third Embodiment

This embodiment differs from the first embodiment in that the metal-containing layer is formed at the topmost portion of a multi-layered interconnect structure. In this embodiment, the metal-containing layer contains the metal element M₁ but contains substantially no nitrogen, similarly to as explained in the first embodiment.

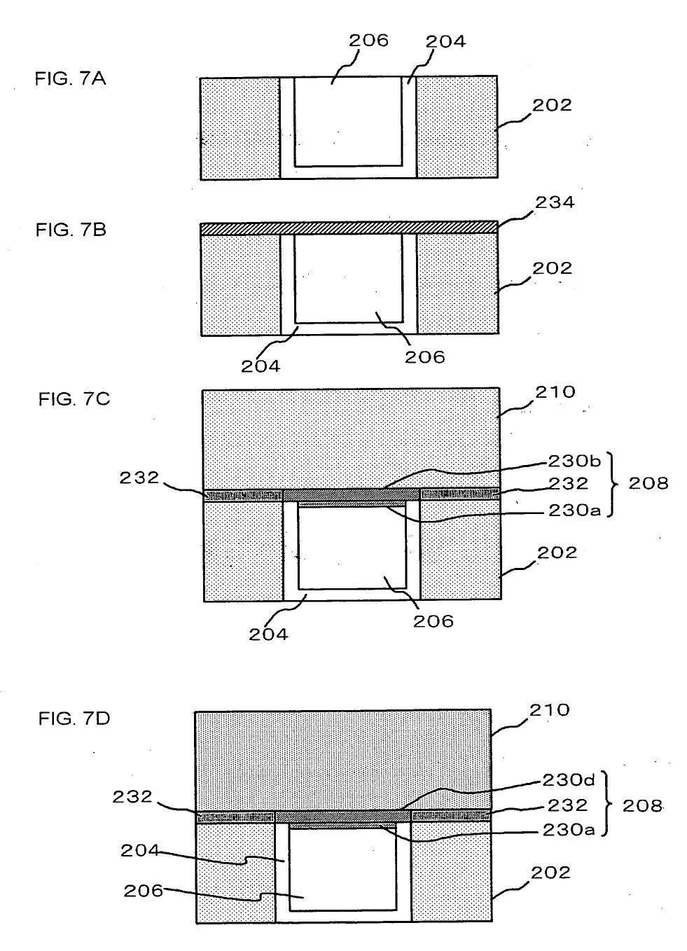

FIGS. 7A to 7D are drawings showing an exemplary procedure for fabricating the semiconductor device 100 of this embodiment.

First, similarly to as shown in FIG. 1A, a lower insulating film 202 is formed on the semiconductor substrate (not shown) having devices such as transistors already formed therein. Next, the interconnect trench is formed in the lower insulating film 202, and the interconnect trench is then filled up with a barrier metal film 204 and an interconnect-forming metal film 206. The barrier metal film 204 and the interconnect-forming metal film 206 may be configured respectively by materials similar to those composing barrier metal film 104 and interconnect-forming metal film 106 explained in the first embodiment. The lower insulating film 202 may be configured by a material similar to that composing the lower insulating film 102 explained in the first embodiment.

Thereafter, the excessive portions of the interconnect-forming metal film 206 and the barrier metal film 204 exposed outside the interconnect trench are removed by CMP. The interconnect structure shown in FIG. 7A can thus be obtained.

Next, the metal layer 234 containing the metal element M₁ but containing substantially no nitrogen is formed on the lower insulating film 202 by the PVD process (FIG. 7B).

Next, an upper insulating film 210 is formed on the metal layer 234. The upper insulating film 210 can be formed typically by the CVD process at approximately 100 to 400° C.

The upper insulating film 210 herein can be configured using a material similar to that composing the upper insulating film 110 explained in the first embodiment. The upper insulating film 210 can be configured also, for example, by a SiO₂ film. In this process, the entire portion of the base structure is exposed to heat, and the metal layer 234 disposed between the lower insulating film 202 and the upper insulating film 210 is converted to an M₁-Si—O-containing layer 232. The metal layer 234 formed on the interconnect-forming metal film 206 allows a part thereof to diffuse into the copper interconnect, to thereby form a Cu-M₁-containing layer 230a. The region of the metal layer 234 formed on the interconnect-forming metal film 206 and in contact with the upper insulating film 210 is converted to M₁-Si—O-containing layer 230b (FIG. 7C).

In this embodiment, the upper insulating film 210 may be configured even by an oxygen-free material. The upper insulating film 210 may be configured, for example, by a SiC film. Also in this case, the entire portion of the base structure is exposed to heat in the process of forming the upper insulating film 210, and the portion of the metal layer 234 in contact with the lower insulating film 202 is diffused with oxygen and silicon contained in the lower insulating film 202, to thereby form therein the M₁-Si—O-containing layer 232. In this process, silicon diffuses into the M₁-Si—O-containing layer 232 also from the upper insulating film 210. The metal layer 234 formed on the interconnect-forming metal film 206 allows a part thereof to diffuse into the copper interconnect, to thereby form a Cu-M₁-containing layer 230a. In the region of the metal layer 234 formed on the interconnect-forming metal film 206 and in contact with the upper insulating film 210, the M₁-Si-containing layer 230d is formed (FIG. 7D).

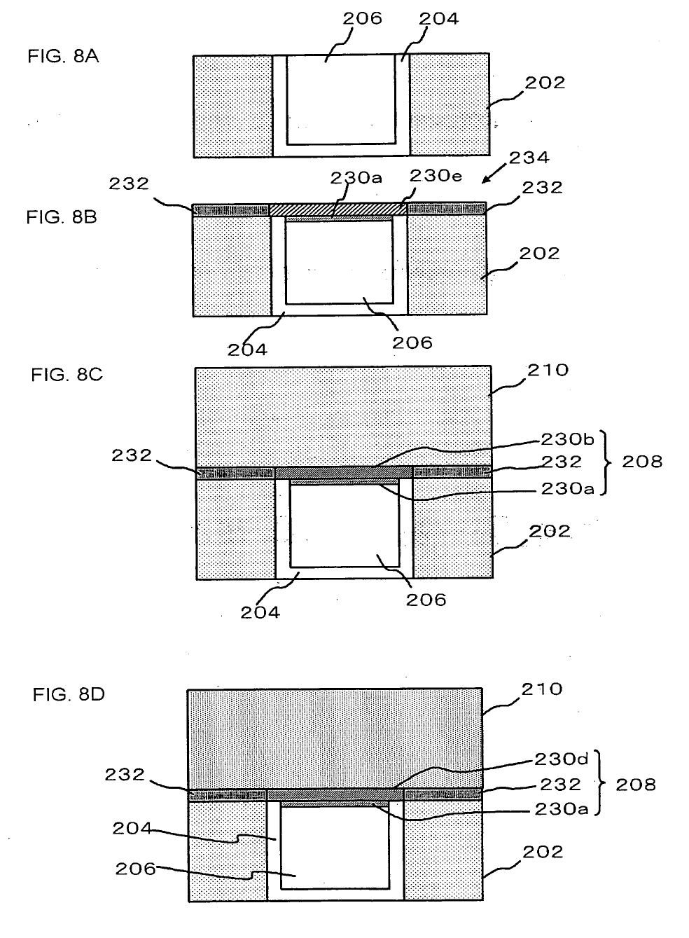

FIGS. 8A to 8D are drawings showing another exemplary procedure for fabricating the semiconductor device 100 of this embodiment.

This embodiment differs from the example shown in FIGS. 7A to 7D in that the metal layer 234 is formed by the ALD process or the CVD process.

The interconnect structure shown in FIG. 8A is formed according to the procedure similar to that explained referring to FIG. 7A. Next, the metal layer 234 containing the metal element M₁ but containing substantially no nitrogen is formed on the lower insulating film 202 by the ALD process or the CVD process at approximately 100 to 250° C.

Because of heat applied in the process of forming the metal layer 234, the M₁-Si—O-containing layer 232 is formed in the metal layer 234 especially in the region in contact with the lower insulating film 202, and the Cu-M₁-containing layer 230a is formed in the region in contact with the interconnect-forming metal film 206. In addition, an M₁-containing layer 230e is formed on the Cu-M₁-containing layer 230a and on the barrier metal film 204.

Next, the upper insulating film 210 is formed on the metal layer 234. The upper insulating film 210 may be formed typically by the CVD process at around 100 to 400° C.

The upper insulating film 210 herein can be configured by a material similar to that composing the upper insulating film 110 explained in the first embodiment, or by a SiO₂ film. The entire portion of the base structure is exposed to heat in this process, and oxygen and silicon also in the upper insulating film 210 diffuse into the M₁-Si—O-containing layer 232 and the M₁-containing layer 230e. As a consequence, the oxygen and silicon contents of the M₁-Si—O-containing layer 232 increase. The M₁-containing layer 230e is converted to the M₁-Si—O-containing layer 230b (FIG. 8C).

The upper insulating film 210 may be configured also by an oxygen-free material. The upper insulating film 210 may be formed, for example, by a SiC film. Also in this case, the entire portion of the base structure is exposed to heat in the process of forming the upper insulating film 210, and by the heating, the portion of the M₁-Si—O-containing layer 232 in contact with the lower insulating film 202 is further diffused with oxygen and silicon contained in the lower insulating film 202. In this process, silicon diffuses into the M₁-Si—O-containing layer 232 also from the upper insulating film 210. The region of the M₁-containing layer 230e formed on the interconnect-forming metal film 206 is diffused with silicon contained in the upper insulating film 210, and thereby the M₁-Si-containing layer 230d is formed (FIG. 8D).

Effects similar to those in the first embodiment can be obtained also by the semiconductor device 100 of this embodiment.

### Fourth Embodiment

This embodiment differs from the second embodiment in that the metal-containing layer is formed at the topmost portion of a multi-layered interconnect structure. In this embodiment, the metal-containing layer contains the metal element M₂ but contains substantially no nitrogen, similarly to as explained in the second embodiment.

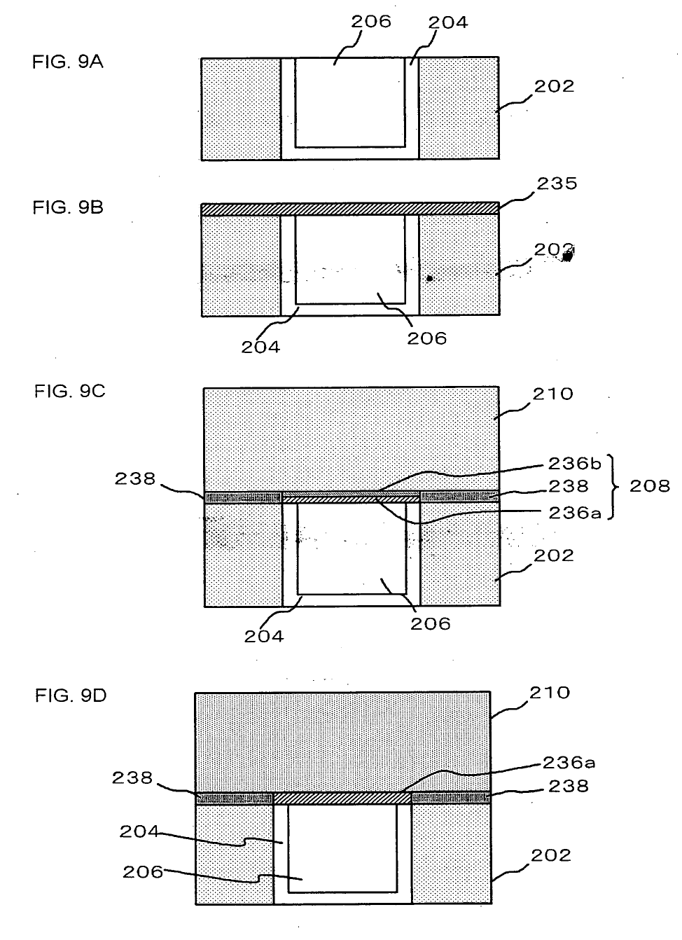

FIGS. 9A to 9D are drawings showing an exemplary procedure for fabricating the semiconductor device 100 of this embodiment.

First, the interconnect structure shown in FIG. 9A is formed according to the procedure similar to that explained in the third embodiment referring to FIG. 7A. Next, a metal layer 235 containing the metal element M₂ but containing substantially no nitrogen is formed on the lower insulating film 202 by the PVD process (FIG. 9B).

Next, the upper insulating film 210 is formed on the metal layer 235 (FIG. 9C). The upper insulating film 210 may be formed, for example, by the CVD process at approximately 100 to 400° C.

The upper insulating film 210 herein may be configured by a material containing silicon and oxygen. The upper insulating film 210 may be configure by a material equivalent to that composing the upper insulating film 110 explained in the first embodiment, or by a SiO₂ film. In this process, the entire portion of the base structure is exposed to heat, and the metal layer 235 disposed between the lower insulating film 202 and the upper insulating film 210 is converted to an M₂-O-containing layer 238. The metal layer 235 formed on the interconnect-forming metal film 206 is diffused with oxygen contained in the upper insulating film 210, specifically in the region in contact with the upper insulating film 210, where an oxide of the metal is formed and thereby a M₂-O-containing layer 236b is formed. The region of the metal layer 235 formed on the interconnect-forming metal film 206, in contact with the interconnect-forming metal film 206 and the barrier metal film 204, remains intact to give the M₂-containing layer 236a.

As another example, the upper insulating film 210 may be configured by an oxygen-free material. The upper insulating film 210 may be formed, for example, by a SiC film. Also in this case, the entire portion of the base structure is exposed to heat in the process of forming the upper insulating film 210, and the portion of the metal layer 235 in contact with the lower insulating film 202 is diffused with oxygen contained in the lower insulating film 202. The M₂-O-containing layer 238 is thus formed. On the other hand, the portion of the metal layer 235 formed on the interconnect-forming metal film 206 remains intact to give the M₂-containing layer 236a (FIG. 9D).

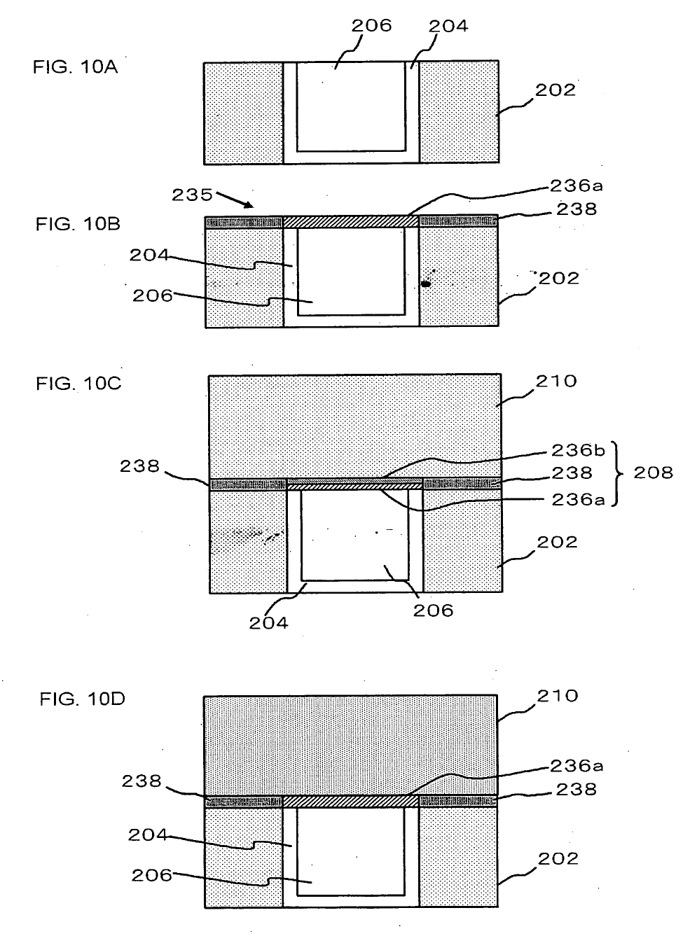

FIGS. 10A to 10D are drawings showing another exemplary procedure for fabricating the semiconductor device 100 of this embodiment.

This embodiment differs from the example shown in FIGS. 9A to 9D in that the metal layer 235 is formed by the ALD process or the CVD process.

The interconnect structure shown in FIG. 10A is formed according to a procedure similar to that explained in the third embodiment referring to FIG. 7A. Next, the metal layer 235 containing the metal element M₂ but containing substantially no nitrogen is formed on the lower insulating film 202, by the ALD process or the CVD process, at approximately 100 to 250° C. The metal element M₂ herein may be same with the metal element M₂ contained in the metal layer 134 explained in the second embodiment.

Because of heat applied in the process of forming the metal layer 235, the M₂-O-containing layer 238 is formed in the metal layer 235 specifically in the region in contact with the lower insulating film 202. In addition, the metal layer 235 remains intact in the region in contact with the interconnect-forming metal film 206 and the barrier metal film 204, to give the M₂-containing layer 236a.

Next, the upper insulating film 210 is formed on the metal layer 235. The upper insulating film 210 can be formed typically by the CVD process at approximately 100 to 400° C.

The upper insulating film 210 herein may be configured by a material equivalent to that composing the upper insulating film 110 explained in the first embodiment, or by a SiO₂ film. In this process, the entire portion of the base structure is exposed to heat, and the metal layer 238 disposed between the lower insulating film 202 and the upper insulating film 210 is further oxidized to have a higher oxygen content. The M₂-O-containing layer 236a formed on the interconnect-forming metal film 206 is oxidized by oxygen contained in the upper insulating film 210 specifically in the region thereof in contact with the upper insulating film 210, to thereby form the M₂-O-containing layer 236b. The region of the metal layer 235 in contact with the interconnect-forming metal film 206 and the barrier metal film 204 remains intact as the M₂-containing layer 236a (FIG. 10C).

The upper insulating film 210 may also be composed of an oxygen-free material. The upper insulating film 210 may be configured, for example, by a SiC film. Also in this case, the entire portion of the base structure is exposed to heat in the process of forming the upper insulating film 210, so that the M₂-O-containing layer 238 in contact with the lower insulating film 202 is further oxidized by the heating. The region of the metal layer 235 formed on the interconnect-forming metal film 206 remains intact as the M₂-containing layer 236a (FIG. 10D).

Effects similar to those in the second embodiment can be obtained also by the semiconductor device 100 of this embodiment.

### EXAMPLE

Table 1 shows results of adhesive force of copper-metal M interface, measured between the metal layer 134, composed of Ta or TaN, and the interconnect-forming metal film 106. The adhesive force was measured by the 4-point bending test.

TABLE 1

| METAL LAYER | ADHESIVE FORCE (J/m²) |
|---|---|
| Ta | 9.79 |
| TaN | 9.00 |

As is known from Table 1, the metal layer 134 showed an improved adhesive force when it was composed of Ta, rather than TaN.

The paragraphs in the above have described the present invention referring to the embodiments and example. The embodiments and example are merely for the exemplary purposes, so that those skilled in the art will readily understand that the present invention can be modified in various ways, and that such modified examples are also within the scope of the present invention.

The individual layers composing the metal-containing layer 108 and the metal-containing layer 208, schematically illustrated and explained above in the first to fourth embodiments, express exemplary configurations which are supposedly most likely to occur, and may have different configurations depending on annealing conditions and so forth. In the individual layer, composition of the elements to be contained may be non-uniform. For example, the M₁-Si—O-containing layer 132 explained in the first embodiment referring to FIG. 3D may be configured as having higher concentrations of Si and O in the surficial portion, and having a higher concentration of metal element M₁ in the center portion. The same will apply also to the other layers.

The present invention is applicable to various modes of embodiment where the interconnect-forming metal film is subjected to surface treatment. For example, the embodiments in the above have described the exemplary cases of forming the multi-layered interconnect structure by the single damascene process, whereas the present invention is also applicable to the case of forming the multi-layered interconnect structure by the dual-damascene process.

It is apparent that the present invention is not limited to the above embodiment, that may be modified and changed without departing from the scope and spirit of the invention.

What is claimed is:

1. A semiconductor device comprising:
a semiconductor substrate;
a first insulating film formed on said semiconductor substrate;
a copper-containing metal film provided so as to fill a recess formed in the surficial portion of said first insulating film, and containing copper as a major constituent;
a second insulating film formed on said first insulating film; and
a metal-containing layer formed between said first insulating film and said second insulating film, and containing a metal element different from copper, said metal-containing layer including a first region in contact with said copper-containing metal film and a second region in contact with said first insulating film and having a composition different from that of said first region, and containing substantially no nitrogen at least in said first region.

2. The semiconductor device as claimed in claim 1, wherein said metal element is selected from the group consisting of Mn, Ta, Al and Ti.

3. The semiconductor device as claimed in claim 1, wherein said metal element is a silicide-forming metal capable of forming a silicide.

4. The semiconductor device as claimed in claim 2, wherein said metal element is a silicide-forming metal capable of forming a silicide.

5. The semiconductor device as claimed in claim 1, wherein said metal-containing layer contains said metal element and silicon as constitutional elements at least in said second region.

6. The semiconductor device as claimed in claim 2, wherein said metal-containing layer contains said metal element and silicon as constitutional elements at least in said second region.

7. The semiconductor device as claimed in claim 1, wherein at least either one of said first insulating film and said second insulating film contains oxygen; and
said metal-containing layer contains an oxide of said metal element at least in said second region.

8. The semiconductor device as claimed in claim 3, wherein at least either one of said first insulating film and said second insulating film contains oxygen; and
said metal-containing layer contains an oxide of said metal element at least in said second region.

9. The semiconductor device as claimed in claim 5, wherein at least either one of said first insulating film and said second insulating film contains oxygen; and
said metal-containing layer contains an oxide of said metal element at least in said second region.

10. The semiconductor device as claimed in claim 1, wherein said metal-containing layer contains said metal element and copper as constitutive elements in said first region.

11. The semiconductor device as claimed in claim 3, wherein said metal-containing layer contains said metal element and copper as constitutive elements in said first region.

12. The semiconductor device as claimed in claim 5, wherein said metal-containing layer contains said metal element and copper as constitutive elements in said first region.

13. The semiconductor device as claimed in claim 7, wherein said metal-containing layer contains said metal element and copper as constitutive elements in said first region.

14. The semiconductor device as claimed in claim 1, wherein said metal-containing layer contains Mn and copper as constitutive elements in said first region, and Mn, silicon and oxygen as constitutive elements in said second region.

15. The semiconductor device as claimed in claim 1, wherein said metal-containing layer functions as a cap film for said copper-containing metal film in said first region.

16. The semiconductor device as claimed in claim 3, wherein said metal-containing layer functions as a cap film for said copper-containing metal film in said first region.

17. The semiconductor device as claimed in claim 5, wherein said metal-containing layer functions as a cap film for said copper-containing metal film in said first region.

18. The semiconductor device as claimed in claim 7, wherein said metal-containing layer functions as a cap film for said copper-containing metal film in said first region.

19. The semiconductor device as claimed in claim 10, wherein said metal-containing layer functions as a cap film for said copper-containing metal film in said first region.

20. A method of fabricating a semiconductor device comprising:
forming a first insulating film on a semiconductor substrate;
forming a recess in the surficial portion of said first insulating film;
filling said recess with a copper-containing metal film containing copper as a major constituent;
removing the excessive portion of said copper-containing metal film exposed outside said recess;
forming, over the entire surface of said first insulating film, a metal layer containing a metal element different from copper and containing substantially no nitrogen;
forming a second insulating film on said metal layer; and
forming, in said metal layer by annealing, a first region in contact with said copper-containing metal film, and a second region in contact with said first insulating film and having composition different from that of said first region.
